(19) United States
(12) Patent Application Publication
(10) Pub. No.: US 2011/0164359 A1
(43) Pub. Date: Jul. 7, 2011

(54) ELECTRONIC DEVICE

(76) Inventors: Chao-Ming CHU, Taipei (TW); Izu-Wei Tai, Taipei (TW); Lionel Zhen Jie Wong, Taipei (TW); Wan-Lynn Ng, Taipei (TW); Cindy Hui Min Liew, Taipei (TW); Daniel Pittella Alenquer, Taipei (TW); Geoffrey Javier, Taipei (TW)

(21) Appl. No.: 12/976,039

(22) Filed: Dec. 22, 2010

(30) Foreign Application Priority Data
Jan. 4, 2010 (CN) 201010000110.X

(51) Int. Cl. H05K 7/00

(52) U.S. Cl. 361/679.01

(57) ABSTRACT

An electronic device includes a host module and an input module. The input module includes a keyboard unit and a plurality of the touch units. The keyboard unit includes a plurality of keys which are electrically connected to the host module. The touch units are disposed adjacent to the keyboard unit and electrically connected to the host module. The electronic device as disclosed brings the convenience for the user to use the electronic device by a plurality of the touch units.

### CROSS REFERENCE TO RELATED APPLICATIONS

This Non-provisional application claims priority under 35 U.S.C. § 119(a) on Patent Application No(s). 201010000110.X filed in People's Republic of China on Jan. 4, 2010, the entire contents of which are hereby incorporated by reference.

### BACKGROUND OF THE INVENTION

1. Field of Invention

The invention relates to an electronic device and, more particularly, to an electronic device with a plurality of touch units.

2. Related Art

With the development of the computer technology, the electronic device such as a notebook computer, a palmtop computer, a personal digital assistant (PDA), a global positioning system (GPS), an electronic book, an electronic dictionary, a game boy, a mobile communication device are designed with powerful functions to meet the different requirements of the customers. Most of the electronic devices usually provide keyboards and/or the touch pad as the interface for users to perform input or control operations.

Taking the notebook computer as an example, FIG. 1 is a diagram showing a conventional notebook computer 1. The notebook computer 1 includes a display screen 11, a host 12, a keyboard 13 and a touch unit 14. The display screen 11 is connected to the host 12. The keyboard 13 and the touch unit 14 are disposed at the host 12 and are connected to the host 12. The keyboard 13 includes a plurality of keys 131. The touch unit 14 is disposed under the keyboard 13 for the user to perform input and control operations conveniently.

The conventional notebook computer 1 includes only one touch unit 14 and most of them, with single-touch feature. Thus, the control actions using the touch unit 14 by the user are limited. In addition, the touch pad cost of the multi-touch feature is much higher. Furthermore, the touch unit 14 is always disposed between the keyboards and the user for convenient use and it is easy to touch the touch unit 14 by mistake to enable an accidental operation when the user uses the keyboards 131 to input characters. Moreover, if the user needs to use the notebook computer 1 for a long time, the location of the touch unit 14 between the user and the keyboards 131 does not meet the ergonomics, and thus the user feels tired easily.

### SUMMARY OF THE INVENTION

It is provided an electronic device which can improve the functionality of the touch unit and improve the convenience in using.

The electronic device in an embodiment includes a host module and an input module. The input module includes a keyboard unit and a plurality of touch units. The keyboard unit includes a plurality of keys electrically connected to the host module. The touch units are disposed adjacent to the keyboard unit and are electrically connected to the host module.

In an embodiment, the touch units are disposed at two sides of the keyboard unit, and each of the touch units includes a touch pad electrically connected to the host module. Each of the touch units further includes a key which is disposed adjacent to the touch pad, and the key is electrically connected to the host module.

In an embodiment, the touch pads are equipped with single-touch or multi-touch features, and the touch pads are allowed to be operated independently or dependently.

The input module of the electronic device includes a plurality of the touch units which are disposed adjacent to the keyboard unit, and the touch units can be used to achieve more operating functions. Meanwhile, touch pads with single-touch feature would not increase the manufacture cost. Moreover, if the touch units are disposed at the two sides of the keyboard unit, the user only needs to move hands to control the keyboard unit and the touch units simultaneously, which is similar to the convenience way that use keyboard and a conventional mouse at the same time. Furthermore, the structure of the electronic device meets the ergonomics requirements, and the user would feel easy even after working for a long time.

These and other features, aspects and advantages of the present invention will become better understood with regard to the following description, appended claims, and accompanying drawings.

### BRIEF DESCRIPTION OF THE DRAWINGS

FIG. 1 is a diagram showing a conventional notebook computer;

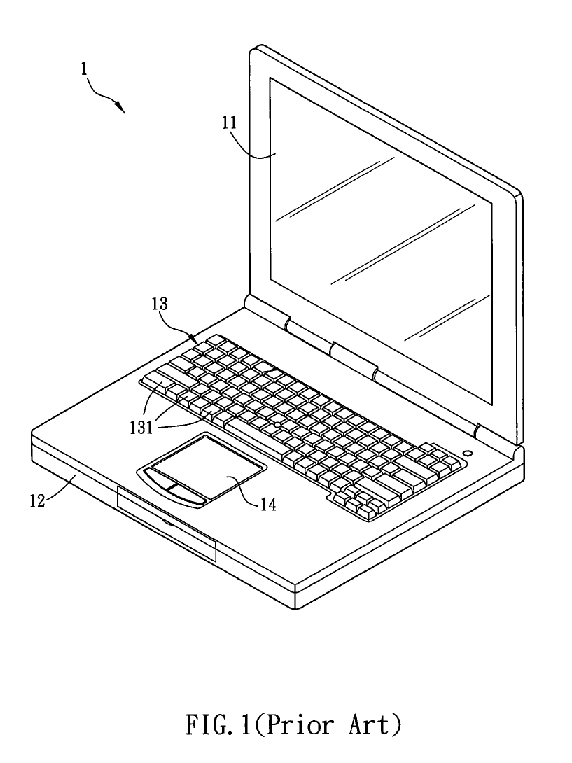

FIG. 2 is a diagram showing an electronic device in an embodiment;

FIG. 3 is a diagram showing an electronic device in operating in an embodiment; and

FIG. 4 is a diagram showing an electronic device in another embodiment.

### DETAILED DESCRIPTION OF THE INVENTION

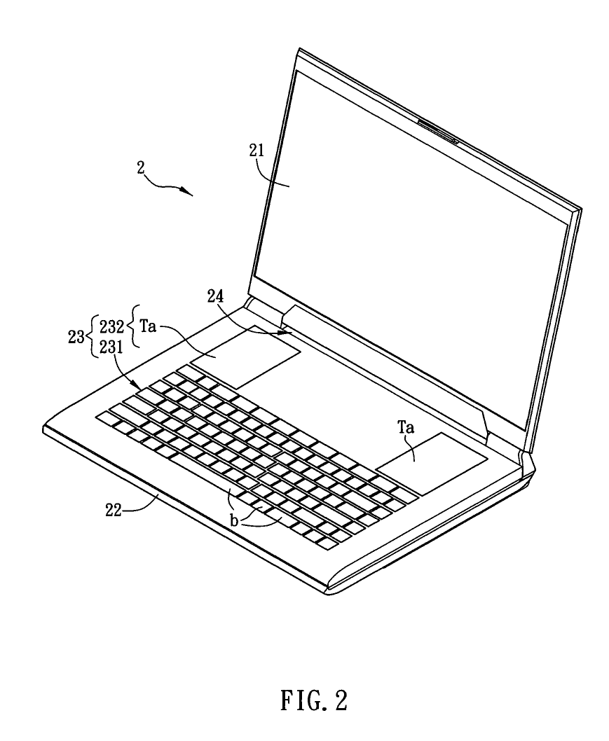

FIG. 2 is a diagram showing an electronic device 2 in an embodiment. The electronic device 2 may be an unportable electronic device or a portable electronic device. The portable electronic device may be a notebook computer, a palmtop computer, a personal digital assistant (PDA), a global positioning system (GPS), an electronic book, an electronic dictionary, a game boy or a mobile communication device. The notebook computer is taken as an example herein, but is not limited thereto.

The electronic device 2 includes a display module 21, a host module 22 and an input module 23. The input module 23 may be integrated into the host module 22 and the display module 21 as a tablet computer such as an E-book.

The display module 21 may be a liquid crystal display (LCD) module. The host module 22 may include a motherboard (not shown) as conventional host computers. In the embodiment, the motherboard of the host module 22 is electrically connected to the display module 21 via wires (not shown) and a pivot 24, but is not limited thereto. The host module 22 may be wiredly or wirelessly connected to the display module 21, and the connection therebetween may be electrical connection or signal connection.

The input module 23 includes a keyboard unit 231 and a plurality of touch units 232. The keyboard unit 231 includes a plurality of keys b, and the keys b may be physical keys or virtual touch keys. Taking the physical keys as an example, the keys b are disposed at the host module 22 and are electrically connected to the motherboard of the host module 22. Thus, the user uses the keys b to input words to control the electronic device 2.

As showed in FIG. 2, the touch units 232 are disposed adjacent to the keyboard unit 23 land electrically connected to the host module 22. In the embodiment, taking the input module 23 with two touch units 232 as an example, but is not limited thereto. The input module 23 may includes more than two touch units 232. The touch units 232 may be disposed at the same side or different sides of the keyboard unit 231, respectively, such as at the left and right sides of the keyboard unit 231, or at the top or bottom sides of the keyboard unit 231 on the host module 22. In the embodiment, the touch units 232 are disposed at the two sides of the top part of the keyboard unit 231, but it is not limited thereto.

In the embodiment, two touch units 232 located at top side of the keyboard include a touch pad Ta, and each of the touch pads Ta may be a resistor touch pad or a capacitor touch pad. Each of the touch pads Ta may equipped with single-touch or multi-touch feature. Furthermore, the electronic device 2 with touch pad Ta having single-touch feature can also have the multi-touch feature by using a hardware configuration or a software controlling method, to achieve expanded applications.

In the embodiment, each of the touch pads Ta may be operated independently. Furthermore, the two touch pads Ta may also be operated simultaneously to achieve the function such as the multi-touch feature. In other words, each of the touch pads Ta of the electronic device 2 in the embodiment may be equipped a touch pad with single touch feature, the user may uses both hands to operate the touch pads Ta, respectively, and thus achieves the function similar to multi-touch.

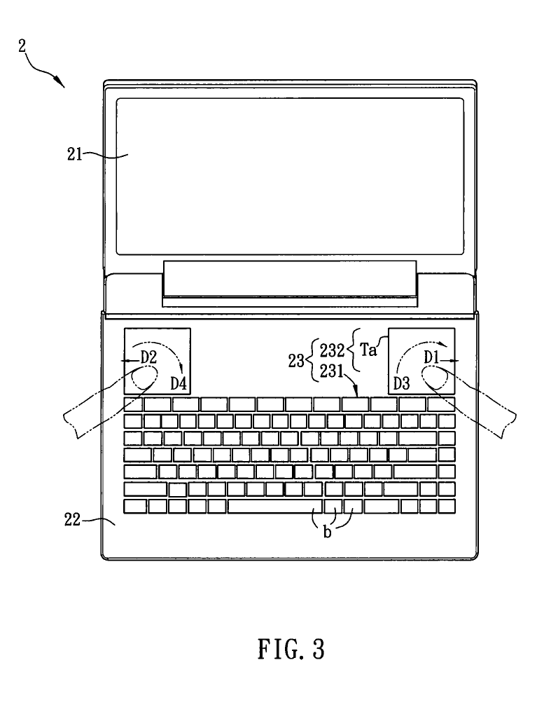

For example, as shown in FIG. 3, when the user moves hands towards the directions D1 and D2, respectively, the electronic device 2 controls the display to show a zoom in function. When the user moves hands against the directions D1 and D2, respectively, the electronic device 2 controls the display as zoom out. When the user moves his or her hands towards the directions D3 and D4, respectively, the electronic device 2 controls the display object to rotate. The function and control method are just examples, which may be updated or modified, but not limited thereto.

In an embodiment, the touch pads Ta may be with multi-touch feature. The user may use one hand to operate one of the touch pad Ta to achieve the multi-touch control. The user may also use both of hands to operate the two touch pads Ta simultaneously to achieve more multi-touch control functions. Herein, the control method is not limited thereto.

As described above, since the touch units 232 of the input module 23 are disposed adjacent to the keyboard unit 231, users may use the touch units 232 to achieve more operating functions within the touch units 232 and the keyboard unit 231. Further, if each of the touch units 232 equips touch pad with single-touch feature, the manufacture cost is controlled low.

Moreover, if the touch units 232 are disposed at the two lateral sides of the keyboard unit 231, the user only needs to move his or her hands parallelly to operate the keyboard unit 231 and the touch units 232, which is similar to the way that use the conventional mouse operating method. Therefore, the structure of the electronic device 2 meets the ergonomics requirements, and the user would not feel tired easily after working for a long time.

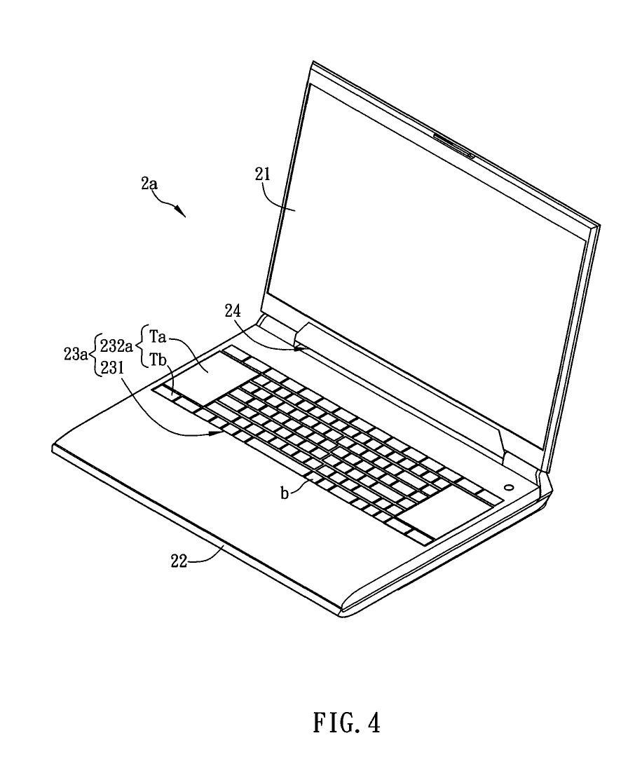

FIG. 4 is a diagram showing an electronic device in another embodiment. Each of the touch units 232a of the input module 23a in the electronic device 2a further includes at least a key Tb. The key Tb is disposed adjacent to the touch pad Ta, and the touch pad Ta and the key Tb are electrically connected to the host module 22. Taking the touch unit 232a with two keys Tb at the bottom of the touch pad Ta as an example. The two keys Tb of the touch unit 232a may include the functions the same as the left and right keys of a mouse.

The touch unit 232a includes one key or more than two keys, further, the touch units 232a can be designed to have one of the touch units 232a includes the keys, and the other one includes no keys. Also, it is to be understood that the keys may not be disposed at the bottom of the touch pad Ta as showed in FIG. 4. It is therefore an embodiment without any limited.

In sum, the touch units of the input module in the electronic device disposed adjacent to the keyboard unit achieves vary functions in any manner, and if the touch units having single-touch feature, the manufacture cost would be keep low.

Moreover, if the touch units are disposed at the two sides of the keyboard unit, respectively, the user only moves hands to operate the keyboard unit and the touch units simultaneously, which is similar to the convenience way that use keyboard and a conventional mouse at the same time. Furthermore, the structure of the electronic device meets the ergonomics requirements, and the user would feel easy even after working for a long time.

Although the present invention has been described in considerable detail with reference to certain preferred embodiments thereof, the disclosure is not for limiting the scope of the invention. Persons having ordinary skill in the art may make various modifications and changes without departing from the scope. Therefore, the scope of the appended claims should not be limited to the description of the preferred embodiments described above.

What is claimed is:

1. An electronic device, comprising:
a host module; and
an input module, including:
a keyboard unit with a plurality of keys, wherein the keys are electrically connected to the host module; and
a plurality of touch units disposed adjacent to the keyboard unit and electrically connected to the host module.

2. The electronic device according to claim 1, wherein the touch units are disposed at two sides of the keyboard unit.

3. The electronic device according to claim 1, wherein each of the touch units comprises a touch pad electrically connected to the host module.

4. The electronic device according to claim 3, wherein each of the touch units further comprises a key disposed adjacent to the touch pad, and the key is electrically connected to the host module.

5. The electronic device according to claim 3, wherein the touch pads are with single-touch feature or multi-touch feature.

6. The electronic device according to claim 3, wherein the touch pads are resistor touch pads or capacitor touch pads.

7. The electronic device according to claim 3, wherein the touch pads operate independently or dependently.

8. The electronic device according to claim 1, which is a notebook computer, a palmtop computer, a personal digital assistant (PDA), a global positioning system (GPS), an electronic book, an electronic dictionary, a game boy or a mobile communication device.
